(19) United States
(12) Patent Application Publication
(10) Pub. No.: US 2026/0172063 A1
(43) Pub. Date: Jun. 18, 2026

(54) ULTRA-LOW-POWER CURRENT-STEERING DIGITAL-TO-ANALOG CONVERTER AND MIXER

(71) Applicant: Silicon Laboratories Inc., Austin, TX (US)

(72) Inventors: Mustafa Koroglu, Austin, TX (US); Pavel Konecny, San Jose, CA (US); Ajmal Vadakkan Kayyil, Oviedo, FL (US)

(21) Appl. No.: 18/980,461

(22) Filed: Dec. 13, 2024

(51) Int. Cl. H04B 1/04; H03M 1/74

(52) U.S. Cl. CPC H04B 1/04; H03M 1/742

(57) ABSTRACT

A transmitter of a wireless communications system includes a digital-to-analog converter (DAC), a baseband filter, and a mixer configured in a stacked circuit between power supply nodes. By stacking those three circuit stages, current-mode signals are used without conversion of intermediate signals into voltage-mode signals. Accordingly, the stacked circuit has a compact structure that reuses bias currents, thereby reducing power consumption and integrated circuit area as compared to embodiments using a serial circuit configuration. The stacked circuit establishes a steady direct current (DC) bias signal at the terminals of transistors of a current-steering DAC that processes time-varying alternating current (AC) signals and reuses that DC bias current to establish a steady DC bias current at the terminals of transistors of the mixer circuit. The stacked circuit can be used in constant envelope modulation applications or in variable envelope modulation applications.

### BACKGROUND

### Field of the Invention

The invention relates to integrated circuits and more particularly to circuits for radio frequency communications.

### Description of the Related Art

In general, a transmitter of a wireless communications device includes a digital circuit that provides digital data to a digital-to-analog converter for conversion into an analog signal. A mixer circuit modulates in-phase and quadrature periodic carrier signals generated by a local oscillator with the analog signal for transmission over the air at radio frequencies. In a conventional wireless communications device, a synthesizer circuit may combine generation of the carrier signal and phase modulation of the carrier signal by the data. However, such implementations are limited to constant envelope modulation techniques and may consume substantial power and area. Accordingly, improved techniques for generating signals for transmission are desired.

### SUMMARY OF EMBODIMENTS OF THE INVENTION

In at least one embodiment, a method for transmitting a signal includes using a bias current to generate a current-mode signal corresponding to a digital code, filtering the current-mode signal to generate a filtered current, and mixing the filtered current with a periodic signal using the bias current to generate a frequency-shifted current-mode signal. Using the bias current may include sourcing the bias current from a first power supply node to a differential node according to the digital code and sinking the bias current from a second differential node to a second power supply node according to the digital code. The method may include converting the frequency-shifted current-mode signal to a rail-to-rail output voltage-mode signal. The method may include providing a first power supply voltage and a second power supply voltage. The first power supply voltage may be greater than the second power supply voltage. The first power supply voltage may be used to generate the bias current and the second power supply node may be used to generate the digital code. The signal may have a variable envelope and the method further includes linearly amplifying an output voltage based on the frequency-shifted current-mode signal.

In at least one embodiment, a transmitter includes a current-steering digital-to-analog converter (DAC) circuit configured to generate a differential current-mode signal through a differential pair of nodes based on an input digital code and a bias current generated by the current-steering DAC circuit. The transmitter includes a smoothing filter configured to generate a filtered current-mode signal through a second differential pair of nodes based on the differential current-mode signal and the bias current. The transmitter includes a differential mixer circuit configured to reuse the bias current to multiply the filtered current-mode signal by a periodic signal to generate a frequency-shifted current-mode signal. The current-steering DAC circuit, the smoothing filter, and the differential mixer circuit may be coupled in a stack between a first power supply node and a second power supply node. The current-steering DAC circuit may include a first current steering DAC circuit having a first bias current generation circuit and a second current steering DAC circuit having a second bias current generation circuit. The transmitter may further include a second smoothing filter coupled between the second current steering DAC circuit and the differential mixer circuit. The current-steering DAC circuit may be complementary to the second current steering DAC circuit. The second current steering DAC circuit and the second smoothing filter may be stacked between the differential mixer circuit and the second power supply node. The transmitter may include a transimpedance amplifier circuit configured to convert the differential current-mode signal to a voltage-mode signal. The transmitter may include a notch filter configured to attenuate spurious tones introduced into the voltage-mode signal by the mixer or the transimpedance amplifier circuit.

### BRIEF DESCRIPTION OF THE DRAWINGS

The present invention may be better understood, and its numerous objects, features, and advantages made apparent to those skilled in the art by referencing the accompanying drawings.

FIG. 1 is a functional block diagram of a transmit path of an exemplary wireless communications system.

FIG. 2 is a functional block diagram of a transmit path of an exemplary wireless communications system consistent with at least one embodiment of the invention.

FIG. 3 is a functional block diagram of a detailed portion of the transmit path of FIG. 2.

FIG. 4 is a circuit diagram of a stacked circuit implementing functions of the transmit path of FIG. 2 consistent with at least one embodiment of the invention.

FIG. 5 is a circuit diagram of a p-type digital-to-analog converter (P-DAC) of the stacked circuit of FIG. 4 consistent with at least one embodiment of the invention.

FIG. 6 is a circuit diagram of an n-type digital-to-analog converter (N-DAC) of the stacked circuit of FIG. 4 consistent with at least one embodiment of the invention.

FIG. 7 illustrates operation of the stacked circuit of FIG. 4 during a first phase of a periodic signal consistent with at least one embodiment of the invention.

FIG. 8 illustrates operation of the stacked circuit of FIG. 4 during a second phase of the periodic signal consistent with at least one embodiment of the invention.

FIG. 9 illustrates an in-phase waveform of the periodic signal input to the stacked circuit of FIG. 4.

FIG. 10 illustrates a quadrature waveform of the periodic signal input to the stacked circuit of FIG. 4.

FIG. 11 illustrates phasor rotation as a function of harmonics of the periodic signal input to the stacked circuit of FIG. 4.

FIG. 12 illustrates aliasing of a frequency component of the output of the buffer circuit of FIG. 2 due to amplitude limiting.

FIG. 13 illustrates a circuit diagram of an exemplary notch filter of the transmit path of FIG. 2 consistent with at least one embodiment of the invention.

FIG. 14 illustrates a frequency response of the exemplary notch filter of FIG. 13 consistent with at least one embodiment of the invention.

FIG. 15 is a functional block diagram of a transmit path of an exemplary wireless communications system using multiple power supply domains consistent with at least one embodiment of the invention.

FIG. 16 is a functional block diagram of a transmit path of an exemplary wireless communications system for non-constant envelope modulation consistent with at least one embodiment of the invention.

FIG. 17 is a functional block diagram of a transmit path using a differential transimpedance amplifier in an exemplary wireless communications system consistent with at least one embodiment of the invention.

The use of the same reference symbols in different drawings indicates similar or identical items.

### DETAILED DESCRIPTION

A transmitter of a wireless communications system includes a digital-to-analog converter (DAC), a baseband filter, and a mixer configured in a stacked circuit between power supply nodes. By stacking those three circuit stages into the stacked circuit, current-mode signals are used without conversion of intermediate signals into voltage-mode signals. Accordingly, the stacked circuit has a compact structure that reuses bias currents, thereby reducing power consumption and integrated circuit area as compared to embodiments using a serial circuit configuration. The stacked circuit establishes a steady direct current (DC) bias signal at the terminals of transistors of a current-steering DAC that processes time-varying alternating current (AC) signals and reuses that DC bias current to establish a steady DC bias current at the terminals of transistors of the mixer circuit. The stacked circuit can be used in constant envelope modulation applications or in variable envelope modulation applications.

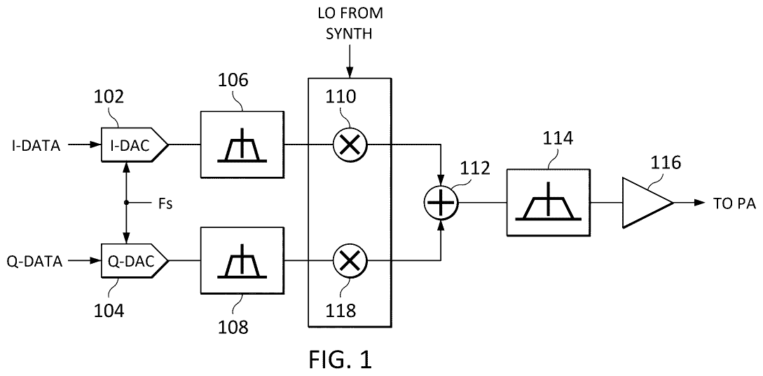

Referring to FIG. 1, a transmit path of a wireless communications system receives digital data for modulation of in-phase and quadrature periodic carrier signals. I-DAC 102 and Q-DAC 104 convert the in-phase and quadrature data signals, respectively, into corresponding in-phase and quadrature analog signals. Baseband filters 106 and 108 are smoothing filters that attenuate or eliminate image signals introduced into the corresponding frequency spectrum by I-DAC 102 and Q-DAC 104, respectively. Mixers 110 and 118 use transistor switches to shift the frequency of the baseband in-phase and quadrature analog signals to radio frequency signals that are combined (e.g., by summing node 112) and filtered by filter 114 to attenuate harmonics introduced by mixer 110. Limiter and buffer 116 provides a constant envelope radio frequency signal to a power amplifier before transmission over a transmission medium (e.g., air). Each circuit coupled in series consumes a corresponding current that flows from a first power supply node (e.g., VDD) to a second power supply node (e.g., ground).

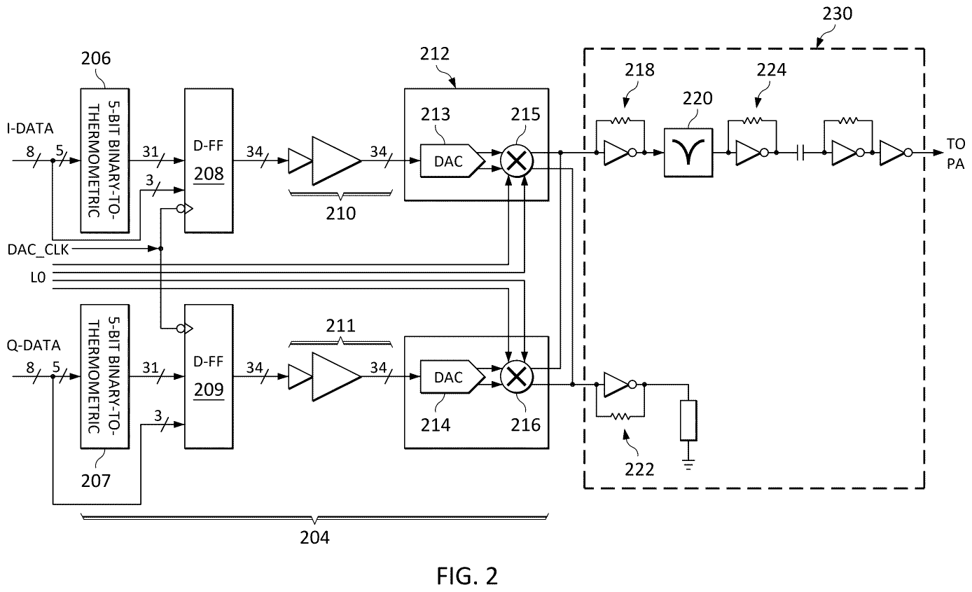

FIG. 2 illustrates an exemplary embodiment of the transmitter path of a wireless communications system that receives baseband digital inputs (e.g., 8-bit binary codes). Binary-to-thermometric converters 206 and 207 convert the corresponding 8-bit binary codes into digital codes usable by DACs 213 and 214, respectively. For example, binary-to-thermometric converters 206 and 207 convert five most-significant bits of the 8-bit binary codes to 31-bit thermometer codes used by DACs 213 and 214, respectively, and three least-significant bits are used directly by DACs 213 and 214. The digital codes are updated and stored in D-flip-flops 208 and 209, respectively using clock signal CLK with a frequency Fₛ (e.g., 40 MHz or 80 MHz). In at least one embodiment, DACs 213 and 214 each include a current-steering DAC element for each bit of the corresponding digital code. A current-steering DAC includes unit elements that steer a corresponding tail current through a first branch or a second branch of the DAC element by a corresponding differential pair of transistors causing only a small voltage excursion at a common node and provides a differential output.

In at least one embodiment, to reduce undesirable effects in the output (e.g., a large error or a nonmonotonicity) caused by device mismatches when an input binary code transitions by one least-significant bit, e.g., transitions from “011 . . . 1” to “10 . . . 0,” the current-steering DAC is segmented or partially segmented. An N-bit input binary code corresponds to 2^{N}−1 thermometer coded bits. The thermometer-coded bits implement a different switching sequence than that for the binary-coded input that improves monotonicity and reduces errors. As the binary inputs transition from “01,” to “10,” to “11,” then a corresponding thermometer code changes from “0001,” to “0011,” to “0111.” At a major carry transition of a binary-coded input, the thermometer code only turns on one more pair of devices that has some characteristics that match the characteristics of the enabled devices rather than turn off multiple pairs of devices and turning on a different pair of devices. However, as the number of bits implemented by a DAC structure increases, the number of current-steering cells needed to implement segmentation substantially increases area and routing (i.e., an N-bit input binary code corresponds to 2^{N}−1 thermometer code-controlled unit cells, e.g., an 8-bit binary code uses 255 thermometer code-controlled unit cells).

Since matching requirements for current sources used to implement the least-significant bits are more relaxed to achieve the same precision of the DAC, in at least one embodiment, a current-steering DAC implements only partial-segmentation. That is, the DAC only uses segmentation for the most-significant bits and uses a binary section for the least-significant bits. For example, in an embodiment the baseband digital input is a binary-coded digital input having a five-bit most-significant bits (coarse) and a three-bit least-significant bits (fine). In at least one embodiment, the five most significant bits of the eight bits of the binary code are converted into 31 thermometer-coded bits and the three least significant bits remain binary coded for a total of 34 bits. However, other encoding schemes consistent with control signals of a current-steering DAC being controlled by the baseband digital input may be used in other embodiments. In an embodiment, binary-to-thermometric converters 206 and 207 convert binary codes into partially segmented digital codes that are stored in flip-flops 208 and 209, respectively. In at least one embodiment, DAC switch drivers 210 convert those digital codes from single-ended signals to differential signals (e.g., enpt32, enpt31, enpt30, . . . , enpt1, enpb2, enpb1, enpb0, ennt32, ennt31, ennt30, . . . , ennt1, ennb2, ennb1, and ennb0).

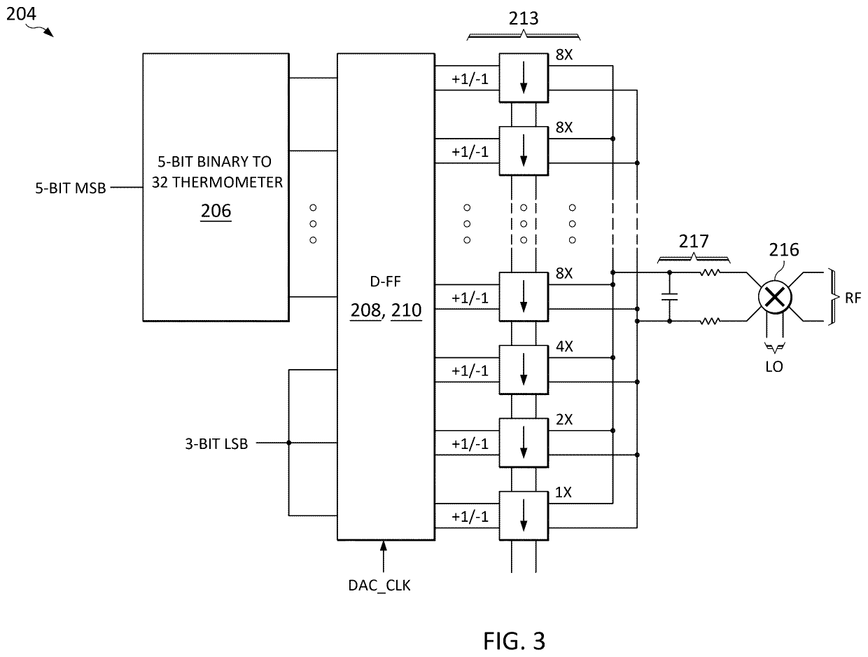

Referring to FIG. 3, in at least one embodiment, a segmented section of DAC 213 includes DAC unit cells that each include a current source having a strength of eight current units and a binary section for three least-significant bits that have strengths that are binary-weighted numbers of current units (e.g., four current units, two current units, and one current unit for a 3-bit binary code). Digital-to-analog converter 213 sums the outputs of the DAC unit cells to drive smoothing filter 217, which provides a filtered analog baseband signal to mixer 216.

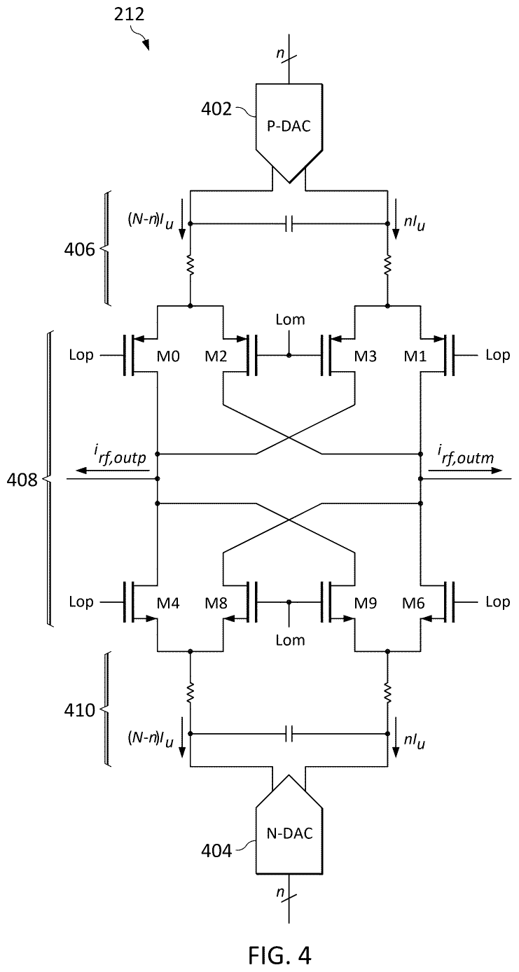

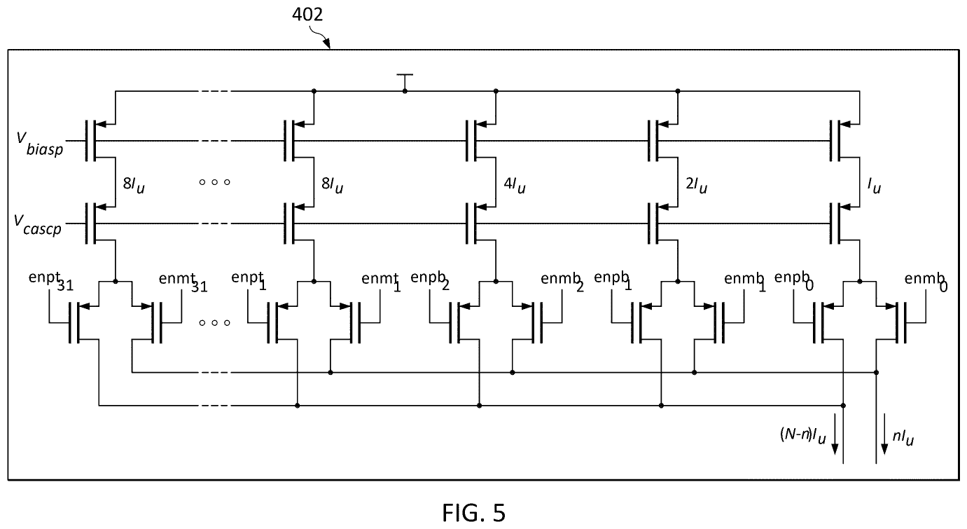

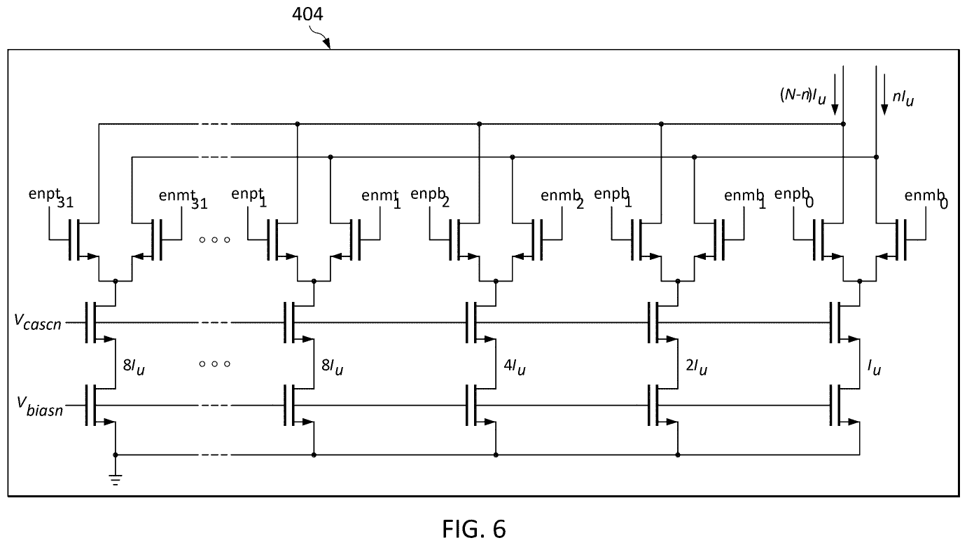

Rather than using a serial topology of the DAC, baseband filter (e.g., smoothing filter), and mixer circuitry of FIGS. 1-3, a circuit topology that combines those functions into a stacked circuit between a power supply node and ground and that reuses a bias current consumes less area and power than the serial topology. Referring to FIGS. 4-6, circuit 212 reuses the bias currents of P-DAC 402, which includes p-type devices, and N-DAC 404, which includes n-type devices, in bias mixer circuit 408, thereby reducing the power consumption of the DAC, mixer, and filtering functions. Bias current flows from power supply node VDD, through P-DAC 402, baseband filter 406, mixer 408, baseband filter 410, and N-DAC 404 before reaching ground. In at least one embodiment, the stacked circuit includes only P-DAC 402, baseband filter 406, and mixer 408, i.e., baseband filter 410, and N-DAC 404 are excluded and replaced with a load (e.g., resistance or transistor). In at least one embodiment, the stacked circuit includes only mixer 408, baseband filter 410, and N-DAC 404, i.e., P-DAC 402 and baseband filter 406 are excluded and replaced with a load (e.g., resistance or transistor). In an embodiment, each DAC unit element is complementary and includes a p-bias transistor and a p-cascode transistor of P-DAC 402 and an n-bias transistor and an n-cascode transistor of N-DAC 404 and is responsive to bias voltage V_{biasp}, cascode voltage V_{cascp}, bias voltage V_{biasn}, and cascode voltage V_{casen}.

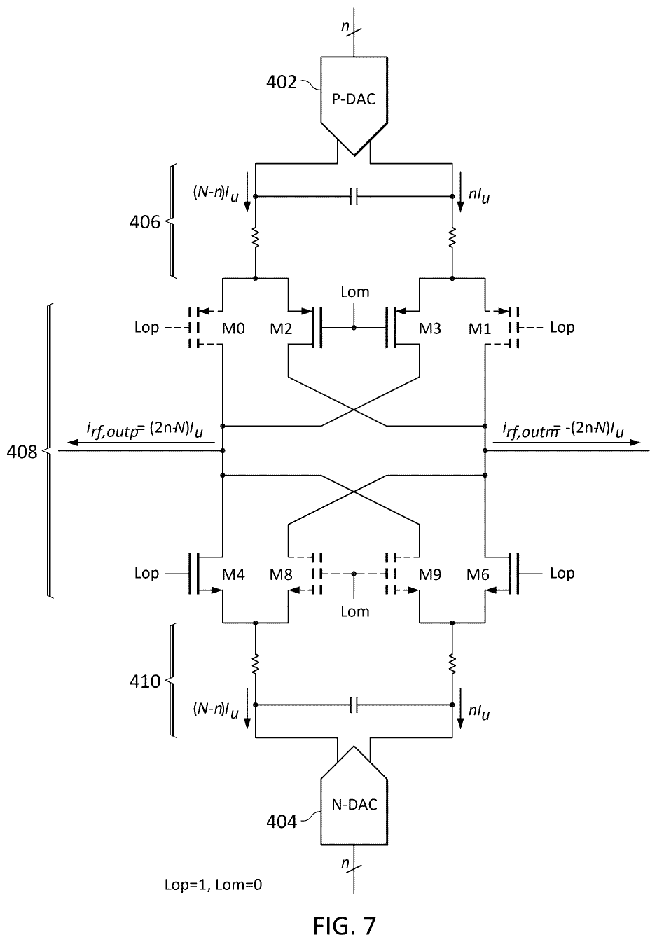

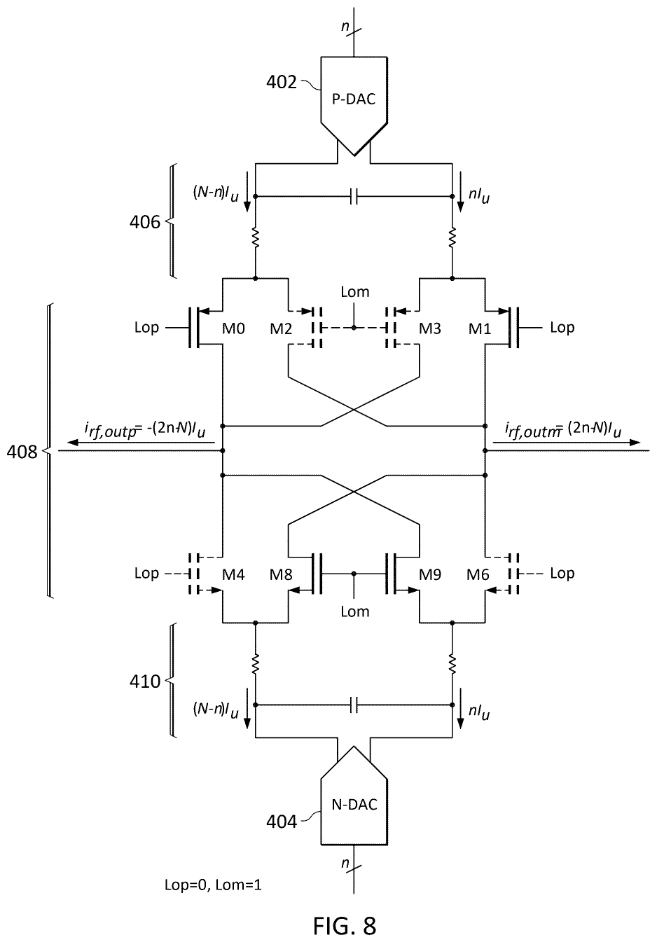

Referring to FIGS. 7 and 8, during normal operation, current N×Iᵤ flows between VDD and ground, where N is 2ⁿ−1 and n is the number of binary-coded bits converted to an analog signal. For example, n is eight for an 8-bit, partially segmented DAC, N=255 and Iᵤ is the unit current source value. In a first phase of the local oscillator signal (e.g., LOP=‘1’ and LOM=‘0,’ where LOP and LOM is the differential local oscillator signal driving the differential pair of input nodes), transistors M2, M3, M4, and M6 are enabled and transistors M0, M1, M8, and M9 are disabled (as indicated by dashed lines in FIG. 7). Accordingly, the differential output current is:

$${i}_{rf , outp} = + ( 2 n - N ) {I}_{u} and {i}_{rf , outm} = - ( 2 n - N ) {I}_{u} ,$$

where n is the number of binary-coded bits converted to an analog signal (e.g., the digital code provided by thermometer coded bits enpt(31:1) and enmt(31:1) and binary coded bits enpb(2:0) and enpm(2:0)).

In a second phase of the local oscillator signal (e.g., where LOP=‘0’ and LOM=‘1’), transistors M2, M3, M4, and M6 are disabled (as indicated by dashed lines in FIG. 8) and transistors M0, M1, M8, and M9 are enabled. Accordingly, the differential output current of mixer 408 is:

$${i}_{rf , outp} = - ( 2 n - N ) {I}_{u} and {i}_{rf , outm} = + ( 2 n - N ) {I}_{u} .$$

The DAC current of N×Iᵤ is reused and flows between VDD and ground via the baseband filter (e.g., baseband filters 406 and 410) and mixer 408.

In an embodiment, mixer 408 multiplies the differential filtered analog signal and the differential local oscillator signal in the time domain. The operation is equivalent to convolving the spectrum of the filtered analog signal with a periodic square wave. The periodic square wave can be represented as:

$$g ( t ) = {\sum }_{m = - ∞}^{∞} {D}_{m} {e}^{jm {ω}_{L O} t} ,$$

where Dₘ is the Fourier series coefficient of the periodic square wave and ω_{LO} is the frequency of the LO clock in radians/second. The frequency domain representation of the local oscillator signal (e.g., LO_I(t) and LO_Q(t)) is the sum of weighted impulses at integer multiples of the local oscillator frequency. However, since the transistors of mixer 408 must operate in the small-signal region of metal-oxide-semiconductor field-effect transistor (MOSFET) operation so that their transconductance varies linearly with the tail current and with the local oscillator signal, mixer 408 has low gain. The transistors of mixer 408 are configured to switch abruptly and completely, e.g., the local oscillator voltage swing and the W/L of the mixer devices are chosen to be large enough to ensure that the mixer devices rapidly steer the tail current from one side of the circuit to the other, and approximate multiplication of the filtered analog signal with multiplication by a square wave. However, multiplication by a square wave translates the spectrum of the filtered analog signal up and down by higher harmonics of the local oscillator signal. Accordingly, a buffer circuit converts the modulated sinusoidal output to a rail-to-rail signal by buffer circuit (i.e., transimpedance amplifier) and introduces an aliased component into the output signal.

Referring to FIGS. 2 and 4, in at least one embodiment of the transmitter path, the in-phase and quadrature output currents of mixers 215 and 216, respectively, are added in the current domain to generate a single-ended, modulated radio frequency output, which is provided to linear transimpedance amplifier 218. Linear transimpedance amplifier 218 converts the current-mode signal to a voltage-mode signal at its output with linear amplification. Load 230 includes linear transimpedance amplifier 218, which provides a low-impedance path for the mixer output current, thereby reducing or minimizing voltage swing at the mixer output. Transimpedance amplifier 222 serves as a dummy amplifier to provide load matching for the unused mixer output. In an embodiment, linear transimpedance amplifier 218 includes an inverter-based transimpedance amplifier that converts the current-mode signal to a voltage-mode signal. Conversion of the current-mode signal to a rail-to-rail signal by load 230 introduces an aliased component into the output signal. For example, odd signal harmonics 3 (ω_{LO}−ω_{IF}), 5 (ω_{LO}−ω_{IF}), and up-converted signal at (3ω_{LO}+ω_{IF}) and (5ω_{LO}−ω_{IF}) produce frequency modulated sidebands at 3 (ω_{LO}−ω_{IF})±4ω_{IF} and 5 (ω_{LO}−ω_{IF})±4ω_{IF}, which alias as (ω_{LO}−ω_{IF})±4ω_{IF}. Filter 220, which includes a notch filter and low pass filter, attenuates the component at 3ω_{LO} and higher frequency components to reduce spurious tones due to aliasing by transimpedance amplifier 224. In an embodiment, transimpedance amplifier 224 and subsequent stages provide rail-to-rail amplification that limits the signal amplitude to levels between VDD and ground. This nonlinear amplification suffers from aliasing, which filter 220 is included to reduce or eliminate.

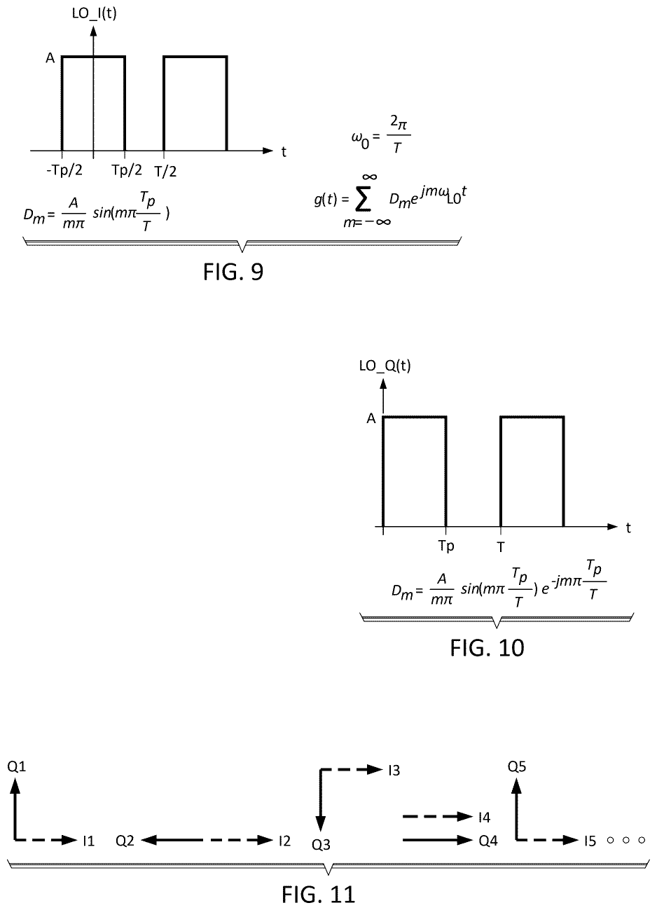

FIGS. 9 and 10 illustrate the local oscillator signal phases and their Fourier series coefficients, Dₘ, which are represented as:

$${D}_{m} = \frac{A}{m π} sin ( m π \frac{{T}_{p}}{T} ) ;$$

$$and$$

$${D}_{m} = \frac{A}{m π} sin ( m π \frac{{T}_{p}}{T} ) {e}^{- jm π \frac{{T}_{p}}{T}} ,$$

where Tₚ is the pulse width of the local oscillator signal, T is the period of the local oscillator signal, and A is the amplitude of the local oscillator square wave signal. FIG. 11 illustrates the phasors of the local oscillator signal (i.e., illustrates the relative phase of the LO_Q with LO_I for different harmonics). The LO_Q phasor rotates with respect to LO_I by kπ/2, where k is the harmonic number. The frequency of the modulated sinusoidal output is shifted up at odd and even harmonics of the local oscillator signal and rotated. The modulated sinusoidal output signal that enters the squaring buffer (i.e., transimpedance amplifier) includes frequency components as follows, where ω_{if} is the baseband input signal frequency (also referred to as the intermediate frequency) and j is the complex number representing \sqrt{−1}:

$$1 : ( Signal ) : {RF}_{OUT} = {I}_{R F} + {Q}_{R F} →︀ cos ( {ω}_{LO} - {ω}_{IF} ) t ;$$

$$2 : ( Second harmonic ) {RF}_{OUT} = {I}_{R F} + {Q}_{R F} \to cos ( 2 {ω}_{L O} - {ω}_{F} - π / 4 ) t + cos ( 2 {ω}_{L O} + {ω}_{IF} + π / 4 ) t ;$$

$$3 : ( Third harmonic ) {RF}_{OUT} = {I}_{R F} + {Q}_{R F} \to 1 / 3 cos ( 3 {ω}_{L O} + {ω}_{IF} ) t ;$$

$$4 : ( Fourth harmonic ) {RF}_{OUT} = {I}_{R F} + {Q}_{R F} \to cos ( 4 {ω}_{L O} - {ω}_{F} + π / 4 ) t + cos ( 4 {ω}_{L O} + {ω}_{IF} - π / 4 ) t ;$$

$$5 : ( Fifth harmonic ) {RF}_{OUT} = {I}_{R F} + {Q}_{R F} \to 1 / 5 cos ( 5 {ω}_{LO} + {ω}_{IF} ) t ;$$

$$7 : ( Sixth harmonic ) {RF}_{OUT} = {I}_{R F} + {Q}_{R F} \to 1 / 7 cos ( 7 {ω}_{LO} + {ω}_{IF} ) t .$$

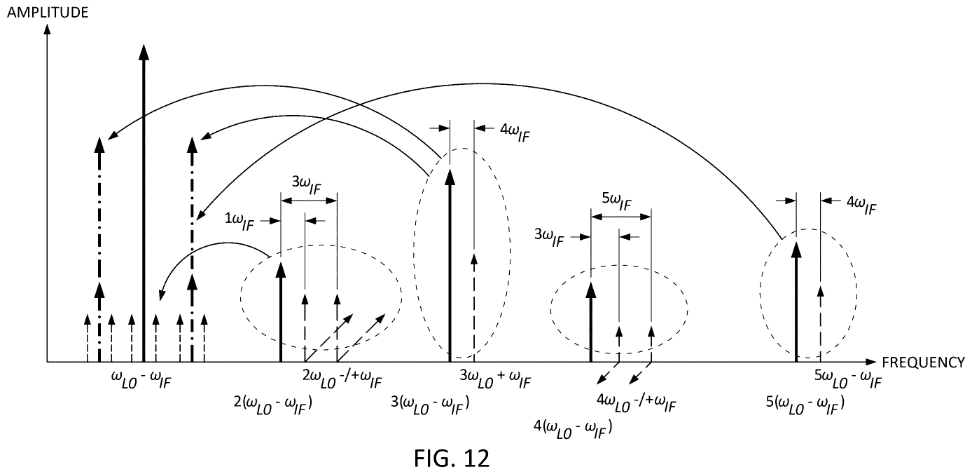

The squaring buffer introduces aliasing when converting the modulated sinusoidal output to a rail-to-rail signal, as illustrated in FIG. 12.
Referring to FIG. 12, in an embodiment, the spectrum observed at the output of the buffer include:
main upconverted signal at (ω_{LO}−ω_{IF});
upconverted signals corresponding to odd harmonics of the local oscillator at (3ω_{LO}+ω_{IF}) and (5ω_{LO}−ω_{IF}), which are subsequently aliased around the desired upconverted signal due to amplitude limiting by the buffer. Signal content at even harmonic frequencies and higher odd harmonic frequencies is assumed to be negligible and ignored; and
harmonic content of the main and aliased signals appearing at odd harmonics at 3(ω_{LO}−ω_{IF}) and 5(ω_{LO}−ω_{IF}).
   In some embodiments, other combinations (even harmonics, etc.) of buffer aliasing may occur.

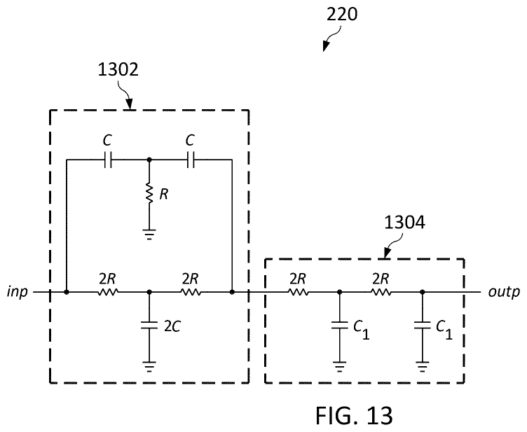

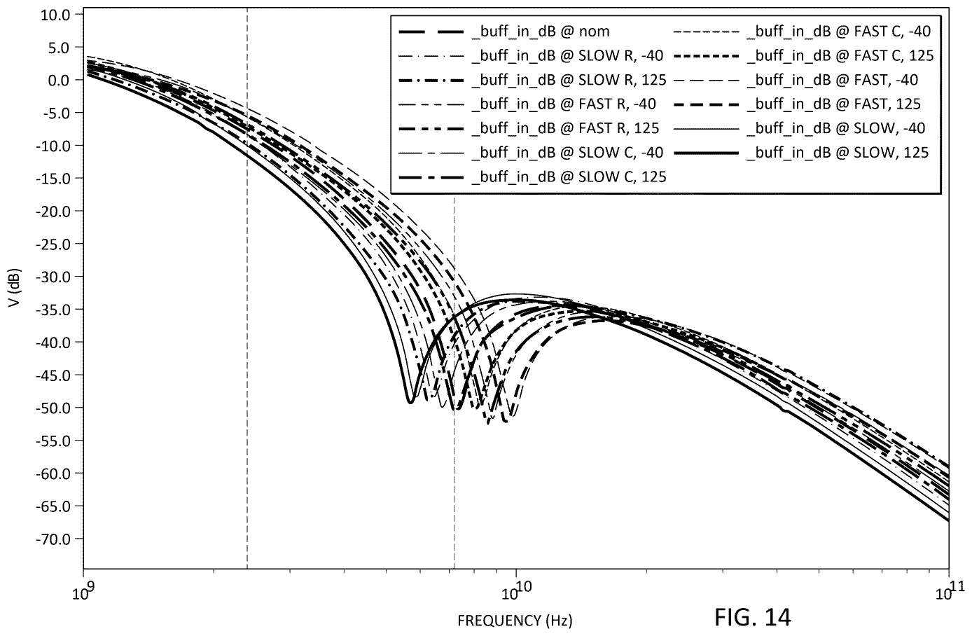

In general, harmonics and up-converted signals in the output signal may corrupt any stages following the mixer that have third-order nonlinearities and may lead to violation of a spectral mask required by a target communications standard. Therefore, the transmitter includes a filter that attenuates the up-converted tones to reduce or eliminate corruption of the signal spectrum due to nonlinearity or clipping characteristics of the subsequent buffer stages. In an embodiment, filter 220 is a passive (e.g., RC) notch filter that attenuates a third harmonic component and higher-order harmonic components in the output signal. The filter components have values that place a notch at 3ωLO of the filter transfer function since the component of the output signal at 3ωLO has substantial magnitude. Other filter transfer functions may be implemented using other filter circuits to reduce spurious tones due to buffer aliasing. An exemplary embodiment of passive filter 220, including notch filter 1302 and low-pass filter 1304, is illustrated in FIG. 13. A transfer function at various process and temperature conditions for an exemplary notch filter having a notch at 3ω_{LO}, where ω_{LO} equals 2×π×f_{LO} and f_{LO} is 2.44 GHz, is illustrated in FIG. 14. In an embodiment, the frequency of the local oscillator varies from 2.4 GHz to 2.48 GHz.

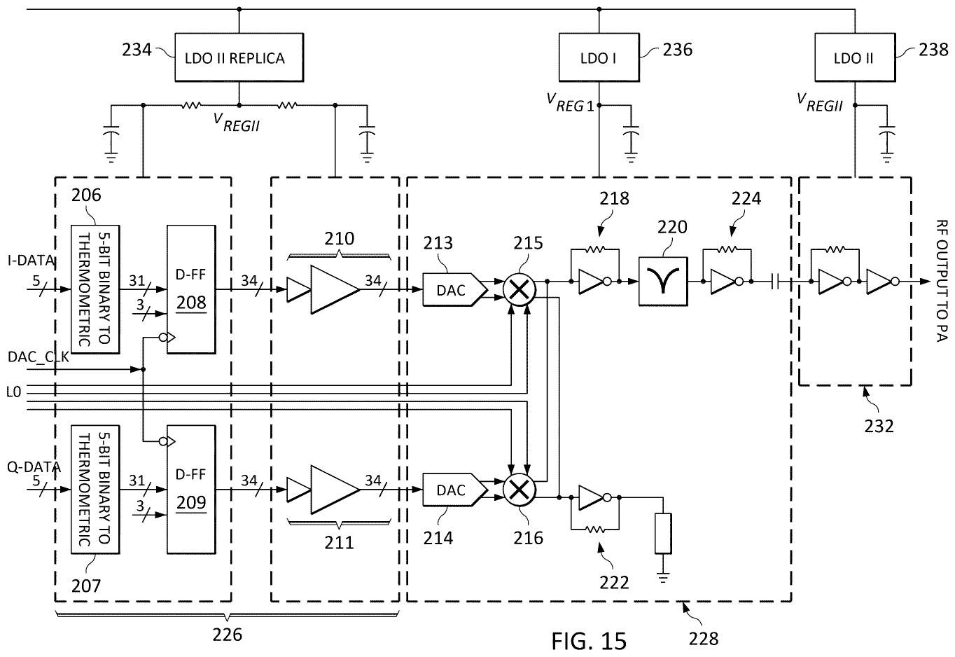

Referring to FIG. 15, in at least one embodiment, the differential-pair of transistors in each current-steering cell are configured to operate in the saturation region of MOSFET operation and thus, the power supply voltage is reduced by at least two drain-to-source voltages (i.e., 2×V_{DS}). Accordingly, in some embodiments, at least two different voltage domains are used. Voltage regulators are included to provide a voltage domain having a boosted power supply voltage where appropriate (e.g., to increase voltage headroom to accommodate the voltage drop requirements of the stacked circuit) and a voltage domain having a regular power supply voltage for other circuitry (e.g., digital circuitry) to contain power consumption. For example, LDO I 236 provides a boosted regulated power supply voltage of 1.15 V to circuit 228, which includes a stacked circuit implementation of DAC 213, filter (not shown), and mixer 215, as described above. LDO II 238 and LDO II replica 234 provide a regulated power supply voltage of 0.9 V to other circuitry (e.g., circuit 226 and circuit 232, respectively, which include digital circuits and an output stage, respectively). In at least one embodiment, circuit 226 uses two separate filtered, power supply domains. One of the filtered power supply domains is dedicated to binary-to-thermometric converters 206 and 207 and D-flip-flops 208 and 209. The other filtered power supply domain is dedicated to switch drivers 210 and 211 to reduce spurious tones in this power supply. Otherwise, that spurious tone can leak via switches in DAC 213 and 214, be upconverted by mixers 215 and 216, and appear as spurious tones in the output signal at an offset of the DAC clock frequency from the RF output frequency. In at least one embodiment, LDO II replica 234 is not a full LDO regulator, but instead is an output stage of LDO II 238. LDO II replica 234 isolates the digital circuits from the output stage of circuit 232. Without that isolation, supply domain coupling can cause digital clock spurious tones to appear at the output of circuit 232.

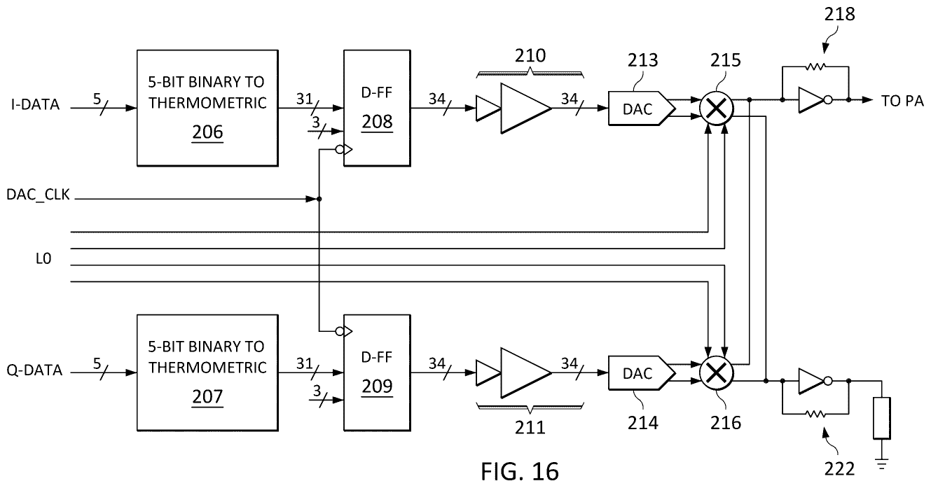

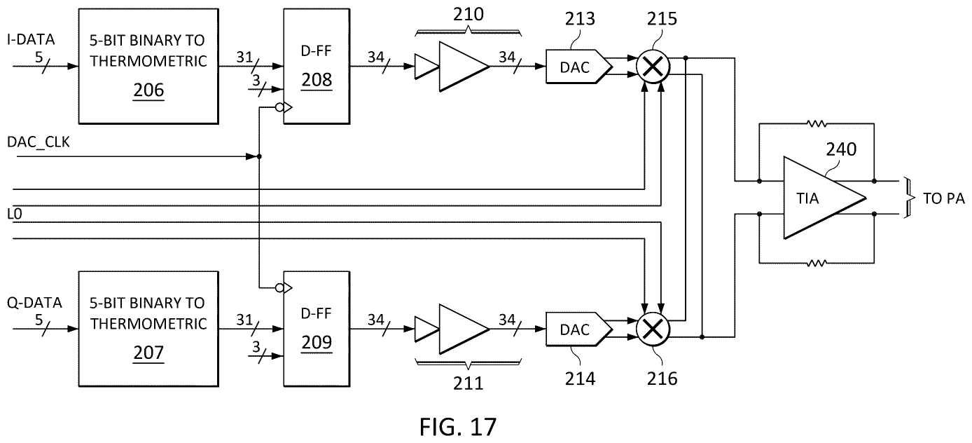

In at least one embodiment, the stacked circuit topology is used in a low intermediate frequency (IF) transmitter (e.g., a transmitter that implements a Bluetooth® protocol) for channel sounding (i.e., High Accuracy Distance Measurement) or other constant envelope modulators (e.g., Minimum-Shift Keying (MSK), Frequency-Shift Keying (FSK), or Binary Phase-Shift-Keying (BPSK)). In other embodiments, the techniques described above are adapted for an IEEE 802.11 protocol or other non-constant envelope modulation protocol (e.g., Orthogonal Frequency-Division Multiplexing (OFDM) or Quadrature Amplitude Modulation (QAM)). Referring to FIG. 2, transimpedance amplifier 224, amplifier, and inverter circuit are omitted for non-constant envelope modulation (i.e., variable envelope) embodiments and the output of linear transimpedance amplifier 218 is provided to a linear power amplifier, as illustrated in FIG. 16. In at least one embodiment, rather than using a single-ended transimpedance amplifier, a differential transimpedance amplifier is used to improve signal-to-noise ratio of the output signal. Referring to FIG. 17, the combined current outputs of mixers 215 and 216 are converted to a differential voltage-mode signal using differential transimpedance amplifier 240.

Thus, techniques for converting digital baseband signals to analog radio frequency signals using a compact, low power, stacked circuit have been disclosed. The stacked circuit includes a low-power, current-steering DAC, filter, and mixer. By stacking those three circuit stages into the stacked circuit, current-mode signals are used without conversion of intermediate signals into voltage-mode signals. The stacked circuit converts baseband digital inputs to upconverted radio frequency analog output signals. In at least one embodiment, a P-DAC, an N-DAC, and a mixer circuit are stacked and use the same bias current to generate a current-mode output signal. In an embodiment, in-phase and quadrature paths each include an embodiment of the stacked circuit, and their current-mode outputs are added and provided to a transimpedance amplifier to convert the combined current-mode signal to a voltage-mode signal. A passive notch filter attenuates a third and higher harmonic components of the voltage-mode signal to reduce the effects of aliasing introduced by the transimpedance amplifier.

The description of the invention set forth herein is illustrative and is not intended to limit the scope of the invention as set forth in the following claims. The terms “first,” “second,” “third,” and so forth, as used in the claims, unless otherwise clear by context, are to distinguish between different items in the claims and do not otherwise indicate or imply any order in time, location or quality. For example, “a first received signal” and “a second received signal,” do not indicate or imply that the first received signal occurs in time before the second received signal. Variations and modifications of the embodiments disclosed herein may be made based on the description set forth herein, without departing from the scope of the invention as set forth in the following claims.

What is claimed is:

1. A method for transmitting a signal comprising:
using a bias current to generate a current-mode signal corresponding to a digital code;
filtering the current-mode signal to generate a filtered current; and
mixing the filtered current with a periodic signal using the bias current to generate a frequency-shifted current-mode signal.

2. The method as recited in claim 1 wherein using the bias current comprises:
sourcing the bias current from a first power supply node to a differential node according to the digital code; and
sinking the bias current from a second differential node to a second power supply node according to the digital code.

3. The method as recited in claim 1 further comprising:
converting the frequency-shifted current-mode signal to a rail-to-rail voltage-mode signal.

4. The method as recited in claim 3 further comprising:
attenuating spurious tones introduced into the rail-to-rail voltage-mode signal by aliasing.

5. The method as recited in claim 1 further comprising:
converting the digital code to a differential control signal.

6. The method as recited in claim 1 wherein the filtering is passive, notch filtering at three times a fundamental frequency of the periodic signal.

7. The method as recited in claim 1 further comprising:
providing a first power supply voltage and a second power supply voltage,
wherein the first power supply voltage is greater than the second power supply voltage, and
wherein the first power supply voltage is used to generate the bias current and the second power supply voltage is used to generate the digital code.

8. The method as recited in claim 1 wherein the signal has a variable envelope and the method further comprises:
linearly amplifying an output signal based on the frequency-shifted current-mode signal.

9. A transmitter comprising:
a current-steering digital-to-analog converter (DAC) circuit configured to generate a differential current-mode signal through a differential pair of nodes based on an input digital code and a bias current generated by the current-steering DAC circuit;
a smoothing filter configured to generate a filtered current-mode signal through a second differential pair of nodes based on the differential current-mode signal and the bias current; and
a differential mixer circuit configured to reuse the bias current to multiply the filtered current-mode signal by a periodic signal to generate a frequency-shifted current-mode signal.

10. The transmitter as recited in claim 9 wherein the current-steering DAC circuit, the smoothing filter, and the differential mixer circuit are coupled in a stack between a first power supply node and a second power supply node.

11. The transmitter as recited in claim 10
wherein the current-steering DAC circuit comprises:
a first current steering DAC circuit including a first bias current generation circuit; and
a second current steering DAC circuit including a second bias current generation circuit, and
wherein the transmitter further comprises a second smoothing filter coupled between the second current steering DAC circuit and the differential mixer circuit,
wherein the current-steering DAC circuit is complementary to the second current steering DAC circuit, and
wherein the second current steering DAC circuit and the second smoothing filter are stacked between the differential mixer circuit and the second power supply node.

12. The transmitter as recited in claim 10 further comprising:
a transimpedance amplifier circuit configured to convert the differential current-mode signal to a voltage-mode signal.

13. The transmitter as recited in claim 12 further comprising:
a notch filter configured to attenuate spurious tones introduced into the voltage-mode signal by the mixer or the transimpedance amplifier circuit.

14. The transmitter as recited in claim 13 wherein the notch filter is a passive circuit configured to attenuate signals having frequencies three times a frequency of the frequency-shifted current-mode signal.

15. The transmitter as recited in claim 13 wherein the stack is configured in a first voltage domain and the transimpedance amplifier circuit and the notch filter are in a second voltage domain, the first voltage domain having a greater voltage level than the second voltage domain.

16. The transmitter as recited in claim 10 further comprising:
digital logic configured to generate the input digital code,
wherein the stack is configured in a first voltage domain and the digital logic is configured in a second voltage domain, the first voltage domain having a greater voltage level than the second voltage domain.

17. The transmitter as recited in claim 16 further comprising:
a switch driver circuit coupled between the digital logic and the stack, wherein the switch driver circuit converts the input digital code to a differential control signal.

18. The transmitter as recited in claim 9
wherein the current-steering DAC circuit comprises a p-type DAC circuit and a n-type DAC circuit, and
wherein the smoothing filter is a passive filter comprising a first passive circuit coupled between the p-type DAC circuit and the differential mixer circuit and a second passive circuit coupled between the n-type DAC circuit and the differential mixer circuit.

19. An apparatus comprising:
means for using a bias current to generate a current-mode signal corresponding to a digital code;
means for filtering the current-mode signal to generate a filtered current; and
means for mixing the filtered current with a periodic signal using the bias current to generate a frequency-shifted current-mode signal.

20. The apparatus as recited in claim 19 further comprising:
means for increasing a power supply voltage across a first power supply node and a second power supply node as compared to a second power supply voltage used to generate the digital code.
